(19) United States
(12) Patent Application Publication
(10) Pub. No.: US 2009/0297846 A1
(43) Pub. Date: Dec. 3, 2009

(54) Double-Walled Carbon Nanotube, Aligned Double-Walled Carbon Nanotube Bulk Structure and Process for Producing the Same

(76) Inventors: Kenji Hata, Ibaraki (JP); Takeo Yamada, Ibaraki (JP); Motoo Yumura, Ibaraki (JP); Sumio Iijima, Ibaraki (JP)

Correspondence Address: WENDEROTH, LIND & PONACK, L.L.P., 1030 15th Street, N.W.,, Suite 400 East, Washington, DC, 20005-1503, US

(21) Appl. No.: 12/085,438

(22) PCT Filed: Nov. 27, 2006
(86) PCT No.: PCT/JP2006/324127

§ 371 Date: Aug. 22, 2008

(30) Foreign Application Priority Data
Nov. 25, 2005 (JP) 2005 341099

(51) Int. Cl. D01F 9/12; B05D 5/00; B32B 9/00; C23C 16/01

(52) U.S. Cl. 428/367; 423/447.1; 427/197; 428/408; 427/249.1; 977/750; 977/752; 977/843

(57) ABSTRACT

An aligned double-walled carbon nanotube bulk structure composed of plural aligned double-walled carbon nanotubes and having a height of 0.1 μm or more and a double-walled carbon nanotube are produced by chemically vapor depositing (CVD) a carbon nanotube in the presence of a metal catalyst with controlled particle size and thickness, preferably in the presence of moisture. According to this, it is possible to provide a double-walled nanotube which is free from inclusion of the catalyst, has high purity, is easy to control the alignment and growth, is able to achieve the fabrication through the formation of a bulk structure and has excellent electron emission characteristic (particularly, a double-walled carbon nanotube bulk structure) and also to provide a production technology thereof.

### TECHNICAL FIELD

The present invention relates to a double-walled carbon nanotube (DWCNT), an aligned double-walled carbon nanotube bulk structure and a process for producing the same and in more detail, to a double-walled carbon nanotube capable of realizing high purity, large scaling and patterning, an aspect of which has not hitherto been achieved, an aligned double-walled carbon nanotube bulk structure and a process for producing the same.

### BACKGROUND ART

With respect to a carbon nanotube (CNT) which is expected for development of a functional material as new electronic device materials, electron emission elements, optical element materials, electric conductive materials, biomaterials and the like, investigations of its yield, quality, use, mass productivity, production process, etc. are keenly advanced.

The present inventors realized the production of a significantly largely scaled single-walled carbon nanotube and its bulk aggregate with high surface area and purity in the presence of a metal catalyst in a state that water vapor is made present in a reaction atmosphere and reported it (Kenji Hata, et al., Water-Assisted Highly Efficient Synthesis of Impurity-Free Single-Walled Carbon Nanotubes, SCIENCE, 2004. 11. 19, Vol. 306, p. 1362-1364 and WO 2006/011655). On the other hand, according to research and development so far, it has been considered possible to produce a multi-walled carbon nanotube (MWCNT) as well as a single-walled carbon nanotube (SWCNT).

However, among such carbon nanotubes (CNTs), with respect to the multi-walled carbon nanotube (MWCNT), technical development of its selective production process and formation of its bulk structure and applications thereof has not progressed so much. Above all, a double-walled carbon nanotube (DWCNT) as the multi-walled carbon nanotube having a minimum wall number is watched for a reason that it is excellent in durability, heat stability and electron emission characteristic, has a large interlayer distance, is able to emit electron at low voltage comparable to a single-walled carbon nanotube and has a life equivalent to the multi-walled carbon nanotube and other reasons. However, it is the actual situation that the technical development is not so large for the foregoing circumstances.

For example, as a production process of a double-walled carbon nanotube (DWCNT), an arc discharge method using a metal catalyst, a peapod-annealing method, a CCVD method using MgO as a catalyst together with a metal, a CCVD method using a carrier such as Al₂O₃ and a metal catalyst and a vapor phase fluidization method using an Fe ferrocene compound as a catalyst, in all of which a carbon compound is used as a carbon source, are known to be representative.

However, in case of the existent arc discharge method, there are involved fundamental problems such as inclusion of the catalyst metal, low yield and no alignment properties, and particularly, difficulty in precise control during the catalyst adjustment; and in the peapod-annealing method, there are involved significant problems such as low yield, no alignment properties and no adaptability to the mass production. Also, in case of the conventional CCVD method, though the yield is relatively high, there are involved problems such as inevitable inclusion of the catalyst, no alignment properties and difficulty in control of the catalyst.

Furthermore, in the vapor phase fluidization method, though the yield is relatively high, and the alignment properties can be controlled, there are involved problems such as inevitable inclusion of the catalyst and difficulty in control.

In the light of the above, in producing a multi-walled carbon nanotube (MWCNT), especially a double-walled carbon nanotube (DWCNT), realization of a new method which is free from inclusion of a catalyst, has high purity, is easy to control the alignment and growth and is able to achieve the fabrication through the formation of a bulk structure and also to achieve the formation of a macro structure has been keenly demanded.

As described previously, the multi-walled carbon nanotube, especially the double-walled carbon nanotube is watched as a material for nano electronic devices, nano reinforcing materials and materials of electron emission elements because of its excellent electric characteristic, thermal characteristic, electron emission characteristic and metal catalyst-supporting ability and the like. Accordingly, in case of effectively utilizing this, it is desirable that a bulk structure which is a form of an aggregate having plural aligned double-walled carbon nanotubes gathered therein is formed and exhibits electric or electronic functionalities or the like. Also, it is desirable that such a carbon nanotube bulk structure is aligned in a specified direction, for example, vertical alignment. Also, it is desirable that its length (height) is largely scaled.

Furthermore, a structure prepared by forming a bulk structure of plural vertically aligned carbon nanotubes and patterning it is very favorable for application to the foregoing nano electronic devices or electron emission elements and the like. If such a vertically aligned double-walled carbon nanotube bulk structure is fabricated, it is expected that the application to nano electronic devices, electron emission elements and the like outstandingly increases.

### DISCLOSURE OF INVENTION

With the background described above, it is an object of the present invention to provide a double-walled carbon nanotube (particularly, an aligned double-walled carbon nanotube bulk structure) which is free from inclusion of a catalyst, has high purity, is easy to control the alignment and growth, is able to achieve the fabrication through the formation of a bulk structure and has excellent electron emission characteristic and also to achieve a production technology thereof.

Also, it is another object of the present invention to provide a production process capable of realizing efficient and selective growth of a multi-walled carbon nanotube, particularly, a double-walled carbon nanotube at a high growth rate by simple means and having excellent mass productivity.

Furthermore, it is further object of the present invention to provide an aligned multi-walled carbon nanotube bulk structure, particularly, a double-walled carbon nanotube bulk structure attaining high purity and outstandingly large-scaled length or height and its production process.

Moreover, it is further object of the present invention to provide the foregoing aligned carbon nanotube bulk structure attaining patterning and its production process.

Also, it is still further object of the present invention to apply the foregoing carbon nanotube with high purity, the foregoing aligned carbon nanotube bulk structure attaining high purity and attaining outstandingly large-scaled length or height, and the foregoing aligned carbon nanotube bulk structure attaining patterning to nano electronic devices, electron emission elements and the like.

For the purpose of solving the foregoing problems, this application provides the following inventions.

(1) A double-walled carbon nanotube, characterized by having an average outer diameter of 1 nm or more and 6 nm or less and a purity of 98 mass % or more.

(2) The double-walled carbon nanotube according to the above (1), wherein its proportion under the coexistence of at least one of a single-walled carbon nanotube and a multi-walled carbon nanotube having three or more walls is 50% or more.

(3) The double-walled carbon nanotube according to the above (1) or (2), wherein it is aligned.

(4) The double-walled carbon nanotube according to the above (3), wherein it is vertically aligned on a substrate.

(5) A process for producing a double-walled carbon nanotube by a method of chemically vapor depositing (CVD) a carbon nanotube in the presence of a metal catalyst, characterized by selectively growing the carbon nanotube by controlling the particle size of a fine particle metal catalyst.

(6) The process for producing a double-walled carbon nanotube according to the above (5), wherein in forming a fine particle metal catalyst by heating a thin film-shaped metal catalyst, the particle size of the fine particle of the metal catalyst is controlled corresponding to the thickness of the thin film.

(7) The process for producing a double-walled carbon nanotube according to the above (5) or (6), wherein the carbon nanotube is selectively grown by controlling the particle size of a catalyst metal such that its proportion under the coexistence of at least one of a single-walled carbon nanotube and a multi-walled carbon nanotube having three or more walls is 50% or more.

(8) The process for producing a double-walled carbon nanotube according to any one of the above (5) to (7), wherein iron is used as the catalyst metal, and its thickness is controlled at 1.5 nm or more and 2.0 nm or less.

(9) The process for producing a double-walled carbon nanotube according to any one of the above (5) to (8), wherein an oxidizing agent is made present in a reaction atmosphere.

(10) The process for producing a double-walled carbon nanotube according to the above (9), wherein the oxidizing agent is water.

(11) The process for producing a double-walled carbon nanotube according to the above (10), wherein moisture of 10 ppm or more and 10,000 ppm or less is made present.

(12) The process for producing a double-walled carbon nanotube according to the above (10) or (11), wherein water vapor is made present at a temperature of 600° C. or higher and 1,000° C. or lower.

(13) The process for producing a double-walled carbon nanotube according to any one of the above (5) to (12), wherein the catalyst is disposed on a substrate, thereby growing the vertically aligned double-walled carbon nanotube on the surface of the substrate.

(14) The process for producing a double-walled carbon nanotube according to any one of the above (5) to (13), wherein a double-walled carbon nanotube having a length of 10 μm or more is obtained.

(15) The process for producing a double-walled carbon nanotube according to any one of the above (5) to (13), wherein a double-walled carbon nanotube having a length of 10 μm or more and 10 cm or less is obtained.

(16) The process for producing a double-walled carbon nanotube according to any one of the above (5) to (15), wherein after growing, the double-walled carbon nanotube is separated from the catalyst or substrate without exposing to a solution and a solvent.

(17) The process for producing a double-walled carbon nanotube according to any one of the above (5) to (16), wherein a double-walled carbon nanotube having a purity of 98 mass % or more is obtained.

(18) The process for producing a double-walled carbon nanotube according to any one of the above (5) to (17), wherein a double-walled carbon nanotube having an average outer diameter of 1 nm or more and 6 nm or less is obtained.

(19) An aligned double-walled carbon nanotube bulk structure, which is characterized by comprising plural aligned double-walled carbon nanotubes having an outer diameter of 1 nm or more and 6 nm or less and a purity of 98 mass % or more.

(20) The aligned double-walled carbon nanotube bulk structure according to the above (19), wherein it has a height of 0.1 μm or more and 10 cm or less.

(21) The aligned double-walled carbon nanotube bulk structure according to the above (19) or (20), wherein a proportion of the double-walled carbon nanotube under the coexistence of at least one of a single-walled carbon nanotube and a multi-walled carbon nanotube having three or more walls is 50% or more.

(22) The aligned double-walled carbon nanotube bulk structure according to any one of the above (19) to (21), wherein it exhibits anisotropy in at least one of optical characteristic, electric characteristic, mechanical characteristic, magnetic characteristic and thermal characteristic in the alignment direction and the vertical direction thereto.

(23) The aligned double-walled carbon nanotube bulk structure according to the above (22), wherein with respect to a degree of anisotropy in the alignment direction and the vertical direction thereto, a larger value is 1:3 or more relative to a smaller value.

(24) The aligned double-walled carbon nanotube bulk structure according to any one of the above (19) to (23), wherein the shape of the bulk structure is patterned into a prescribed shape.

(25) The aligned double-walled carbon nanotube bulk structure according to any one of the above (19) to (24), wherein it is vertically aligned on a substrate.

(26) The aligned double-walled carbon nanotube bulk structure according to any one of the above (19) to (25), wherein the bulk structure is a thin film.

(27) A process for producing an aligned double-walled carbon nanotube bulk structure by patterning a metal catalyst on a substrate and chemically vapor depositing (CVD) plural carbon nanotubes in the presence of the metal catalyst such that they are aligned in a prescribed direction relative to the surface of the substrate to form a bulk structure, characterized by selectively growing a double-walled carbon nanotube by controlling the particle size of the metal catalyst as a fine particle.

(28) The process for producing an aligned double-walled carbon nanotube bulk structure according to the above (27), wherein in forming a fine particle metal catalyst by heating a thin film of the metal catalyst, the particle size of the metal catalyst fine particle is controlled corresponding to the thickness of the thin film.

(29) The process for producing an aligned double-walled carbon nanotube bulk structure according to the above (27) or (28), wherein the carbon nanotube is selectively grown by controlling the particle size of the metal catalyst such that its proportion under the coexistence of at least one of a single-walled carbon nanotube and a multi-walled carbon nanotube having three or more walls is 50% or more.

(30) The process for producing an aligned double-walled carbon nanotube bulk structure according to the above (28) or (29), wherein iron is used as the metal catalyst, and its thickness is controlled at 1.5 nm or more and 2.0 nm or less.

(31) The process for producing an aligned double-walled carbon nanotube bulk structure according to any one of the above (27) to (30), wherein an oxidizing agent is made present in a reaction atmosphere.

(32) The process for producing an aligned double-walled carbon nanotube bulk structure according to the above (31), wherein the oxidizing agent is water.

(33) The process for producing an aligned double-walled carbon nanotube bulk structure according to the above (32), wherein moisture of 10 ppm or more and 10,000 ppm or less is made present.

(34) The process for producing an aligned double-walled carbon nanotube bulk structure according to the above (32) or (33), wherein moisture is made present at a temperature of 600° C. or higher and not higher than 1,000° C.

(35) The process for producing an aligned double-walled carbon nanotube bulk structure according to any one of the above (27) to (34), wherein a bulk structure having a height of 0.1 μm or more and 10 cm or less is obtained.

(36) The process for producing an aligned double-walled carbon nanotube bulk structure according to any one of the above (27) to (35), wherein the shape of the bulk structure is controlled by patterning of the metal catalyst and growth of the carbon nanotube.

(37) The process for producing an aligned double-walled carbon nanotube bulk structure according to any one of the above (27) to (36), wherein after growing, the bulk structure is separated from the catalyst or substrate without exposing to a solution and a solvent.

(38) The process for producing an aligned double-walled carbon nanotube bulk structure according to any one of the above (27) to (37), wherein a bulk structure having an average outer diameter of 1 nm or more and 6 nm or less and a purity of 98 mass % or more is obtained.

(39) The process for producing an aligned double-walled carbon nanotube bulk structure according to any one of the above (27) to (38), wherein a bulk structure having anisotropy in at least one of optical characteristic, electric characteristic, mechanical characteristic, magnetic characteristic and thermal characteristic in the alignment direction and the vertical direction thereto is obtained.

(40) The process for producing an aligned double-walled carbon nanotube bulk structure according to the above (39), wherein a bulk structure in which with respect to a degree of anisotropy in the alignment direction and the vertical direction thereto, a larger value is 1:3 or more relative to a smaller value is obtained.

(41) The process for producing an aligned double-walled carbon nanotube bulk structure according to any one of the above (27) to (40), wherein the alignment of the prescribed direction is vertical alignment.

As described above, as compared with the conventional double-walled carbon nanotubes, the double-walled carbon nanotube and double-walled carbon nanotube bulk structure of the present invention are highly purified such that inclusion of a catalyst, by-products, etc. is suppressed and are extremely useful in applications to nano electronic devices, electron emission elements and the like.

Also, according to the process of the present invention, it is possible to produce a double-walled carbon nanotube and its bulk structure with high selectivity and high efficiency by extremely simple means inclusive of control of the particle size of fine particles of the catalyst metal, control of the thickness of a catalyst metal thin film enabling to realize it and the presence of an oxidizing agent such as water vapor in the reaction system. In addition, it is possible to prolong the life of the metal catalyst, realize the efficient growth thereof at a high growth rate and devise to achieve mass production. Also, the carbon nanotube grown on a substrate can be easily peeled off from the substrate or catalyst.

Then, it is to be especially emphasized that according to the production process of the present invention, the double-walled carbon nanotube coexisting with a single-walled carbon nanotube (SWCNT) and a multi-walled carbon nanotube of three or more, its proportion of presence following the growth can be freely selected and controlled by controlling the particle size of the catalyst metal and further the thin film of the catalyst metal. For example, the proportion of the double-walled carbon nanotube can be selectively controlled at 50% or more, 80% or more, and further 85% or more. On the other hand, it is also possible to increase the proportion of the single-walled carbon nanotube or the multi-walled carbon nanotube of three or more walls. According to such control, the behavior of its application is largely expanded.

Also, among the aligned double-walled carbon nanotube bulk structure of the present invention, one which is patterned can be expected to have various applications in addition to the application to nano electronic devices and the like likewise those described above.

Furthermore, according to the present invention, in addition to applications to heat dissipators, heat conductors, electric conductors, reinforcing materials, electrode materials, batteries, capacitors or super capacitors, electron emission elements, adsorbing agents, optical elements and the like, various applications are realized.

### BRIEF DESCRIPTION OF DRAWINGS

FIG. 1 is a schematic view showing a production process of the present invention.

FIG. 2 is a schematic view of a production apparatus of a double-walled carbon nanotube or an aligned double-walled carbon nanotube bulk structure.

FIG. 3 is a schematic view of a production apparatus of a double-walled carbon nanotube or an aligned double-walled carbon nanotube bulk structure.

FIG. 4 is a schematic view of a production apparatus of a double-walled carbon nanotube or an aligned double-walled carbon nanotube bulk structure.

FIG. 5 is a schematic view of a production apparatus of a double-walled carbon nanotube or an aligned double-walled carbon nanotube bulk structure.

FIG. 6 is a schematic view of a production apparatus of a double-walled carbon nanotube or an aligned double-walled carbon nanotube bulk structure.

FIG. 7 is a schematic view of a separator to be used for peeling off an aligned double-walled carbon nanotube bulk structure from a substrate or a catalyst.

FIG. 8 is a schematic view of a separator to be used for peeling off an aligned double-walled carbon nanotube bulk structure from a substrate or a catalyst.

FIG. 9 is a diagrammatic view of a heat dissipator using an aligned double-walled carbon nanotube bulk structure and an electron part provided with this heat dissipator.

FIG. 10 is an external appearance view of a double-walled carbon nanotube film in Example 1.

FIG. 11 shows an SEM image of a vertex in Example 1.

FIG. 12 shows a first TEM image in Example 2.

FIG. 13 shows a second TEM image.

FIG. 14 shows a third TEM image.

FIG. 15 shows a Raman spectrum and a thermal analysis diagram in Example 2.

FIG. 16 shows a TEM image in Example 2.

FIG. 17 is a diagram showing the relationship of a thickness of catalyst iron and a central outer diameter of tube distribution in the Examples.

FIG. 18 is a diagram showing the relationship of a tube outer diameter and tube distribution.

FIG. 19 is a diagram showing the expected relationship between a central outer diameter of tube distribution and existence probability.

FIG. 20 is a diagram exemplifying the relationship between a tube outer diameter and a count number regarding high-concentration double-walled nanotubes.

FIG. 21 shows an atomic force microscopic image exemplifying a finely divided state of a catalyst.

FIG. 22 is a schematic view showing steps of patterning growth in Example 4.

FIG. 23 shows a first SEM image of patterned double-walled nanotubes.

FIG. 24 shows a second SEM image.

FIG. 25 shows a third SEM image.

FIG. 26 shows a fourth SEM image.

FIG. 27 shows a fifth SEM image.

FIG. 28 is a diagram showing a nitrogen adsorption isotherm and a BET specific surface area in Example 5.

### BEST MODE FOR CARRYING OUT THE INVENTION

The present invention has the characteristic features as described above, and embodiments thereof will be described hereinafter.

First of all, a double-walled carbon nanotube of the present invention will be described.

The double-walled carbon nanotube of the present invention is characterized by having an average outer diameter of 1 nm or more and 6 nm or less, and preferably 2 nm or more and 5 nm or less and a purity of 98 mass % or more, preferably 99 mass % or more, and more preferably 99.9 mass % or more.

Here, the purity as referred to in this description is expressed by mass % of the carbon nanotube in a product. The measurement of such purity is performed through measurement from the elemental analysis result using fluorescent X rays.

In this double-walled carbon nanotube, in the case where a purification treatment is not performed, the purity immediately after the growth (as-grown) is a purity of a final product. The purification treatment may be performed as the need arises.

Also, the double-walled carbon nanotube can be converted to one having been aligned, and preferably one having been vertically aligned on a substrate.

The vertically aligned double-walled carbon nanotube according to the present invention is one in which the incorporation of the catalyst, by-products and the like is suppressed and highly purified and has a high purity as a final product not comparable with the conventional materials.

Then, the aligned double-walled carbon nanotube bulk structure of the present invention is composed of plural aligned double-walled carbon nanotubes and characterized by having a height of 0.1 μm or more.

The “structure” as referred to in the description of this application means an aggregate having plural aligned double-walled carbon nanotubes gathered therein and exhibits functionalities such as electric or electronic characteristic and optical characteristic.

In this aligned double-walled carbon nanotube bulk structure, its purity is 98 mass % or more, more preferably 99 mass % or more, and especially preferably 99.9 mass % or more. In the case where a purification treatment is not performed, the purity immediately after the growth (as-grown) is a purity of a final product. The purification treatment may be performed as the need arises. This aligned double-walled carbon nanotube bulk structure can be converted to one having been subjected to prescribed alignment, and preferably one having been vertically aligned on a substrate.

With respect to the height (length) of the aligned double-walled carbon nanotube bulk structure of the present invention, its preferred range varies depending upon the use. When used as large-scaled one, its lower limit is preferably 0.1 μm, more preferably 20 μm, and especially preferably 50 μm; and its upper limit is preferably 2.5 mm, more preferably 1 cm, and especially preferably 10 cm.

In the light of the above, the aligned double-walled carbon nanotube bulk structure according to the present invention is one in which the incorporation of the catalyst, by-products and the like is suppressed and highly purified and has a high purity as a final product not comparable with the conventional materials.

Also, since the aligned double-walled carbon nanotube bulk structure according to the present invention has a greatly large-scaled height, it can be expected to have various applications in addition to applications to nano electronic devices and the like as described later.

Also, since the aligned double-walled carbon nanotube bulk structure according to the present invention has alignment properties, it exhibits anisotropy in at least one of optical characteristic, electric characteristic, mechanical characteristic, magnetic characteristic and thermal characteristic anisotropy in the alignment direction and the vertical direction thereto. In this double-walled carbon nanotube bulk structure, a degree of anisotropy in the alignment direction and the vertical direction thereto is preferably 1:3 or more, more preferably 1:5 or more, and especially preferably 1:10 or more. Its upper limit is about 1:100. Such large anisotropy makes it possible to apply to various articles utilizing anisotropy, for example, heat exchangers, heat pipes and reinforcing materials.

For example, the double-walled carbon nanotube and its bulk structure having the foregoing characteristic features of the present invention are produced by making a metal catalyst present in a reaction system by the CVD method. In this CVD method, likewise the conventional methods, hydrocarbons, especially lower hydrocarbons, for example, methane, ethane, propane, ethylene, propylene and acetylene can be favorably used as a carbon compound as a starting carbon source. These may be used singly or in combination of two or more kinds thereof, and the use of a lower alcohol, for example, methanol and ethanol or an oxygen-containing compound having a low carbon number, for example, acetone and carbon monoxide is considerable so far as it is tolerable as the reaction condition.

Any gas can be used as an atmospheric gas of the reaction so far as it does not react with the carbon nanotube and is inert at the growth temperature. Examples of such a gas include helium, argon, hydrogen, nitrogen, neon, krypton, carbon dioxide, chlorine and mixed gases thereof. In particular, helium, argon, hydrogen and mixed gases are preferable.

Any pressure can be applied as the atmospheric pressure of the reaction so far as it falls within the range of pressure at which carbon nanotubes have been produced so far. It is preferably 10² Pa or more and 10⁷ Pa (100 atmospheres) or less, more preferably 10⁴ Pa or more and 3×10⁵ Pa (3 atmospheres) or less, and especially preferably 5×10 Pa or more and 9×10 Pa or less.

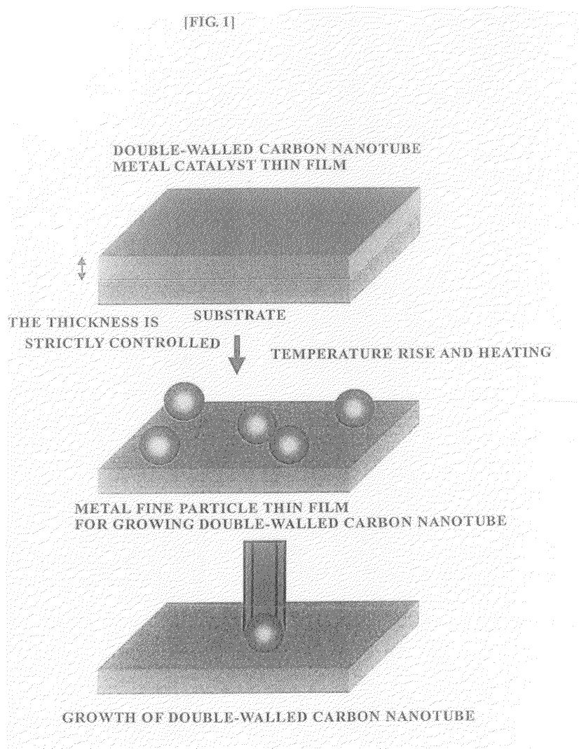

As described above, a metal catalyst is made present in the reaction system. Any catalyst, for example, metals (including alloys) such as iron, molybdenum, cobalt and aluminum can be properly used as this catalyst so far as it has been used in the production of carbon nanotubes so far. The production process of the present invention is characterized in that the particle size of fine particles of such a metal catalyst is limited, thereby making it possible to achieve selective growth of a double-walled carbon nanotube and its bulk structure. With respect to the control of the particle size of fine particles of this metal catalyst, in heating a thin film of the metal catalyst to form fine particles, it is possible to control the particle size by the thickness of the thin film. The outline of this characteristic feature is shown in FIG. 1.

As shown in FIG. 1, for example, a thin film of a metal catalyst having a strictly controlled thickness is first provided on a substrate. For example, an iron chloride thin film, an iron thin film prepared by sputtering, an iron-molybdenum thin film, an alumina-iron thin film, an alumina-cobalt thin film and an alumina-iron-molybdenum thin film can be enumerated.

When the provided thin film is heated at high temperatures, fine particles of the metal catalyst are formed, and the particle size thereof can be regulated by the thickness of the thin film. The selectivity of the formation of the double-walled carbon nanotube can be increased by the particle size. Also, the proportion of presence of the double-walled carbon nanotube in the bulk structure can be increased by uniformity of the particle size of the plural metal catalyst fine particles. That is, as compared with other single-walled carbon nanotubes and multi-walled carbon nanotubes of three or more walls, the selectivity and proportion of presence of the double-walled nanotube in the formed carbon nanotube are increased by the thickness of the metal catalyst. Actually, in the present invention, the proportion of the double-walled carbon nanotube can be increased to 50% or more, further 80% or more or 85% or more.

In the light of the above, in the process of the present invention for producing a double-walled carbon nanotube and its bulk structure, any existence amount of the catalyst as the thin film can be used within the range of amount at which carbon nanotubes have been produced so far. For example, in the case where an iron metal catalyst is used, the thickness of the thin film is preferably 0.1 nm or more and 100 nm or less, more preferably 0.5 nm or more and 5 nm or less, and especially preferably 1.5 nm or more and 2 nm or less.

As to the disposition of the catalyst, so far as a method for disposing the metal catalyst in the foregoing thickness is concerned, an appropriate method such as sputtering vapor deposition can be employed. Also, a large amount of double-walled carbon nanotubes can also be simultaneously produced utilizing patterning of the metal catalyst as described later.

The temperature at the growth reaction in the CVD method is determined appropriately while taking into account the reaction pressure and types of the metal catalyst, starting carbon source and oxidizing agent and the like. It is desirable that the temperature range is set up such that the effect of the addition of the oxidizing agent is thoroughly revealed. As to the most desirable temperature range, a temperature at which a by-product which deactivates the catalyst, for example, amorphous carbon or a graphite layer is removed by the oxidizing agent is a lower limit, and a temperature at which a main product, for example, a carbon nanotube is not oxidized by the oxidizing agent is an upper limit. Specifically, in case of water vapor, it is effective that the temperature is preferably 600° C. or higher and 1,000° C. or lower, and more preferably 650° C. or higher and 900° C. or lower. Also, it is effective that in case of oxygen, the temperature is preferably not higher than 650° C., and more preferably not higher than 550° C.; and that in case of carbon dioxide, the temperature is preferably not higher than 1,200° C., and more preferably not higher than 1,100° C.

Then, the presence of the oxidizing agent which is one of the characteristic features in the present invention brings an effect for enhancing the activity of the catalyst at the time of CVD growth reaction and prolonging the activity life. As a result of this synergistic effect, the formed carbon nanotubes largely increase. For example, when (water) water vapor as the oxidizing agent is made present, the activity of the catalyst becomes largely high, and the life of the catalyst is prolonged. In the case where (water) water vapor is made absent, the catalyst activity and catalyst life are reduced to an extent that it is markedly difficult to quantitatively evaluate them.

Also, when water vapor as the oxidizing agent is made present by means of addition or the like, the height of the vertically aligned double-walled carbon nanotube bulk structure can be largely increased. This demonstrates that the double-walled carbon nanotube is more efficiently formed due to the oxidizing agent (water). The matter that the activity of the catalyst and the life of the catalyst and as a result, the height thereof are markedly increased due to the oxidizing agent (water) is one of the greatest characteristic features of the present invention. The knowledge that the height of the vertically aligned double-walled carbon nanotube bulk structure is largely increased due to the oxidizing agent has not been known at all before this application and is an epoch-making matter which has been first found out by the inventors of this application.

Though the function of the oxidizing agent to be added in the present invention is not elucidated yet at present, it may be considered as follows.

In a usual growth stage of carbon nanotube, during the growth, the catalyst is covered by a by-product formed during the growth, for example, amorphous carbon or a graphite layer, whereby the catalyst activity is reduced, the life becomes short, and the catalyst is rapidly deactivated. The catalyst is covered by the by-product. When the by-product covers the catalyst, the catalyst is deactivated. However, when the oxidizing agent is present, the by-product formed during the growth, for example, amorphous carbon or a graphite layer is oxidized to convert to a CO gas, etc. and then removed from the catalyst layer. According to this, the activity of the catalyst is increased, and the life of the catalyst is prolonged. As a result, it is estimated that the growth of the carbon nanotube is efficiently advanced, thereby obtaining a vertically aligned double-walled carbon nanotube bulk structure with a remarkably increased height.

As the oxidizing agent, water, oxygen, ozone, hydrogen sulfide, an acidic gas, a lower alcohol such as ethanol and methanol, an oxygen-containing compound having a low carbon number such as carbon monoxide and carbon dioxide and mixed gases are also effective. Of these, water, oxygen, carbon dioxide and carbon monoxide are preferable, with water being especially preferable for use.

The amount of the oxidizing agent is not particularly limited, and it may be a very small amount. For example, in case of water, usually, its amount is preferably 10 ppm or more and 10,000 ppm or less, more preferably 50 ppm or more and 1,000 ppm or less, and further preferably 200 ppm or more and 700 ppm or less. From the viewpoints of preventing the deterioration of the catalyst and enhancing the catalyst activity due to the presence of water, in case of water, it is desirable to make its existence amount fall within the foregoing range.

Due to the presence of this oxidizing agent, the growth of carbon nanotube which is conventionally completed for at most about 2 minutes endures for several ten minutes, and the growth rate is increased by 100 times or more, further even 1,000 times as compared with the conventional method.

In the process of the present invention, though a carbon nanotube chemical vapor deposition (CVD) apparatus is desirably provided with an apparatus for feeding an oxidizing agent, it is not particularly limited with respect to configuration and structure of other reaction apparatus and reactor for achieving the CVD method. Any of known conventional apparatus such as a thermal CVD furnace, a heating furnace, an electric furnace, a drying furnace, a thermostat, an atmospheric furnace, a gas replacement furnace, a muffle furnace, an oven, a vacuum heating furnace, a plasma reactor, a micro plasma reactor, an RF plasma reactor, an electromagnetic wave heating reactor, a microwave irradiation reactor, an infrared ray irradiation heating furnace, an ultraviolet ray heating reactor, an MBE reactor, an MOCVD reactor and a laser heating apparatus can be used.

The disposition and configuration of the apparatus for feeding an oxidizing agent are not particularly limited. Examples thereof include feed as a gas or a mixed gas, feed upon vaporization of an oxidizing agent-containing solution, feed upon vaporization and liquefying of an oxidizing agent solid, feed using an oxidizing agent atmospheric gas, feed utilizing spraying, feed utilizing a high pressure or reduced pressure, feed utilizing injection, feed utilizing a gas flow and composite feed of these measures. The feed is taken using a bubbler, a vaporizer, a mixer, a stirrer, a diluter, a sprayer, a nozzle, a pump, a syringe, a compressor, etc. or a system composed of a combination of a plurality of these instruments.

Also, in order to precisely control and feed a very small amount of the oxidizing agent, the apparatus may be provided with a purification apparatus for performing the removal of the oxidizing agent from the raw material gas and carrier gas. In that case, the apparatus feeds a controlled amount of the oxidizing agent in a later stage to the raw material gas and carrier gas from which the oxidizing agent has been removed in any one of the foregoing measures. The foregoing measures are effective when a very small amount of the oxidizing agent is contained in the raw material gas and carrier gas.

Furthermore, in order to precisely control and stably feed the oxidizing agent, the apparatus may be equipped with a measurement apparatus for measuring the concentration of the oxidizing agent. In that case, stable feed of the oxidizing agent which is small in change with time may be achieved by subjecting the measured value to feedback to an oxidizing agent flow adjustment unit.

Furthermore, the measurement apparatus may be an apparatus for measuring the synthesis amount of the carbon nanotube or may be an apparatus for measuring a by-product formed due to the oxidizing agent.

Furthermore, in order to synthesize a large amount of the carbon nanotube, the reactor may be equipped with plural substrates or may be equipped with a system for achieving continuous feed and discharge.

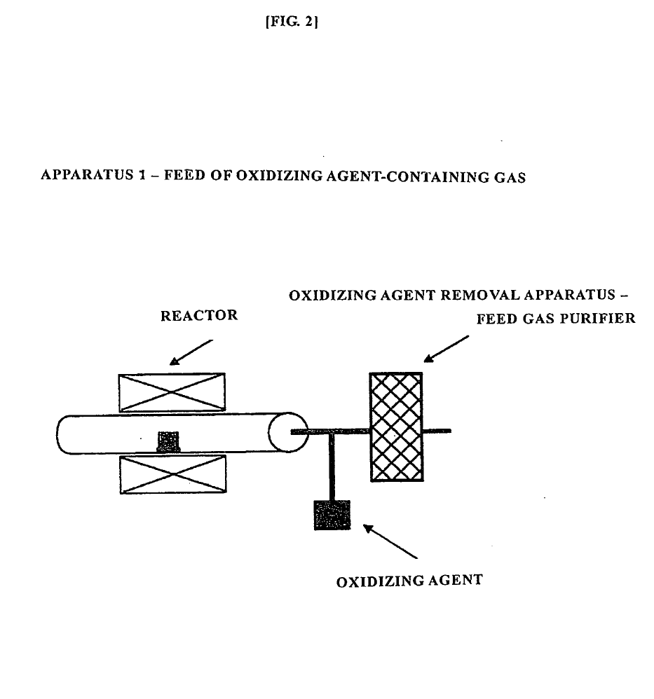

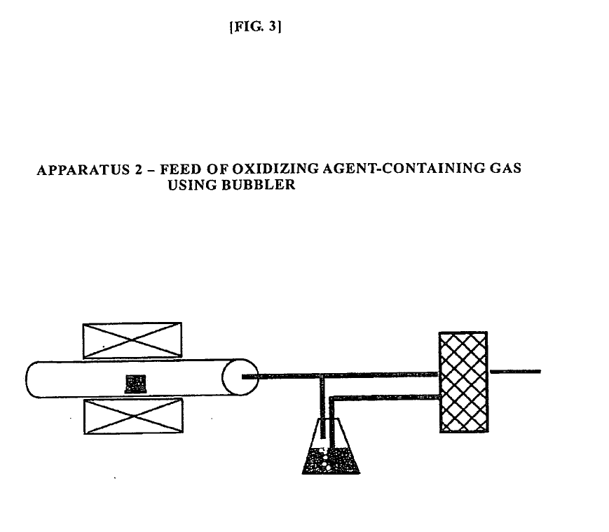

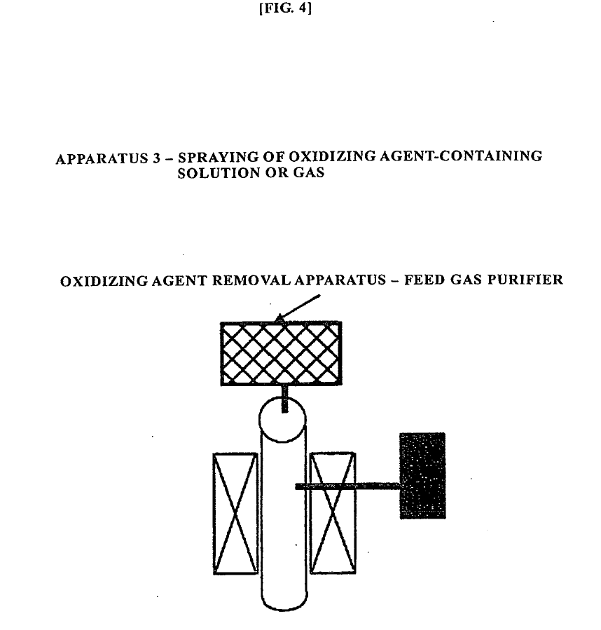

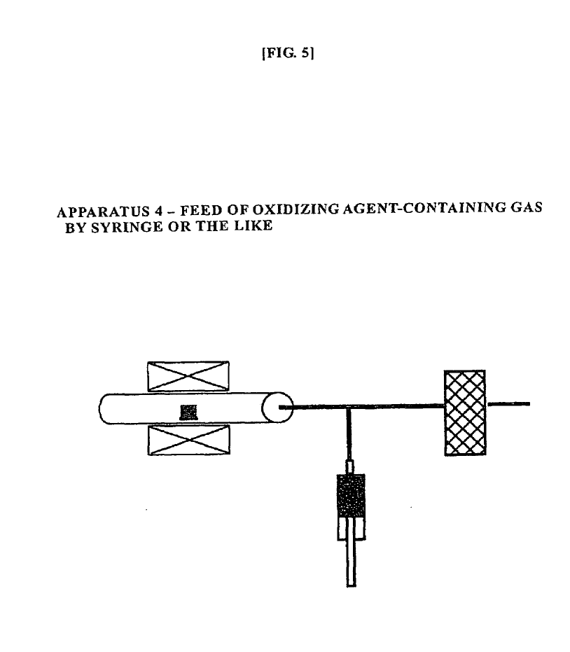

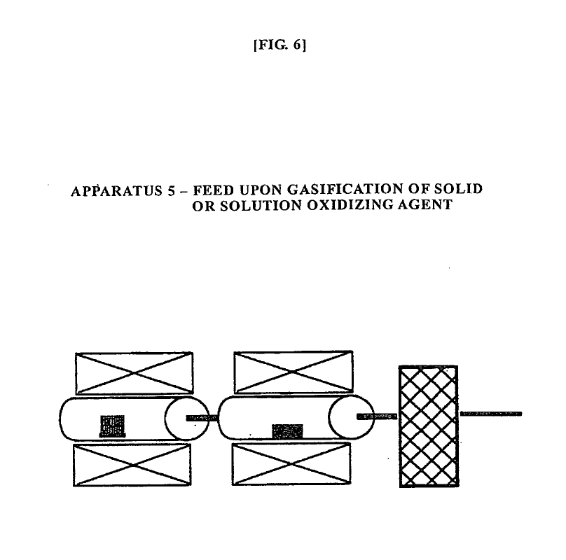

Examples of the CVD apparatus which is favorably used for the purpose of carrying out the process of the present invention are schematically shown in FIGS. 2 to 6.

According to the process of the present invention, a catalyst is disposed on a substrate, whereby a vertically aligned double-walled carbon nanotube can be grown on the surface of the substrate. In that case, any substrate can be properly used so far as carbon nanotubes have been produced therefrom so far, and the following can be exemplified.

(1) Metals and semiconductors such as iron, nickel, chromium, molybdenum, tungsten, titanium, aluminum, manganese, cobalt, copper, silver, gold, platinum, niobium, tantalum, lead, zinc, gallium, germanium, indium, gallium, germanium, arsenic, indium, phosphorus and antimony; alloys thereof; and oxides of these metals and alloys.
(2) Thin films, sheets, plates, powders and porous materials of the foregoing metals, alloys and oxides.
(3) Non-metals and ceramics such as silicon, quartz, glass, mica, graphite and diamond; and wafers and thin films thereof.

The height (length) of the vertically aligned double-walled carbon nanotube to be produced in the process of the present invention varies depending upon the use; its lower limit is preferably 0.1 μm, more preferably 20 μm, and especially preferably 50 μm; and though its upper limit is not particularly limited, from the viewpoint of actual use, it is preferably 2.5 mm, more preferably 1 cm, and especially preferably 10 cm.

In case of growing the double-walled carbon nanotube on the substrate, it can be easily peeled off from the substrate or catalyst.

As a method for peeling off the double-walled carbon nanotube, there is a method for physically, chemically or mechanically peeling off it from the substrate. For example, a method for peeling off it using an electric field, a magnetic field, a centrifugal force or a surface tension; a method for mechanically stripping off it directly from the substrate; a method for peeling off it from the substrate using pressure or heat; and the like can be employed. As a simple peeling-off method, there is a method for directly picking up it with a pair of tweezers and peeling off it from the substrate. More favorably, the double-walled carbon nanotube can be cut off using a thin cutter such as a cutter blade. Furthermore, the double-walled carbon nanotube can also be stripped out from the substrate by sucking using a vacuum pump or a vacuum cleaner. Also, after peeling-off, it is possible to grow the vertically aligned double-walled carbon nanotube by remaining the catalyst on the substrate and newly utilizing it.

Accordingly, such a double-walled carbon nanotube is extremely useful in applications to nano electronic devices, nano optical elements, electron emission elements and the like.

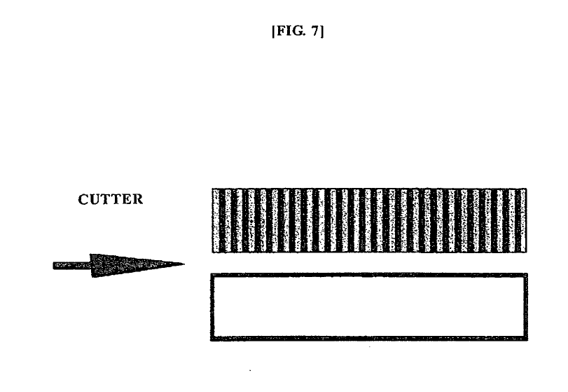

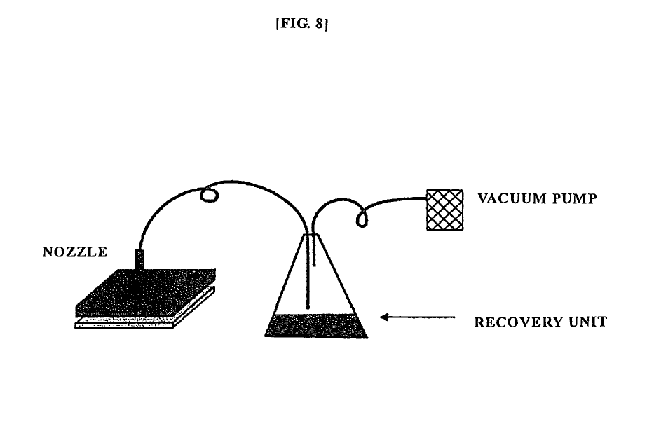

Representative examples of the apparatus for peeling off or separating the double-walled carbon nanotube from the substrate or catalyst are schematically shown in FIGS. 7 and 8. In the case where the double-walled carbon nanotube is grown on the substrate, it can be easily peeled off from the substrate or catalyst. As the method and apparatus for peeling off the double-walled carbon nanotube, the previously described methods are employed.

The double-walled carbon nanotubes produced by the process of the present invention may be subjected to a purification treatment the same as in the conventional technology as the need arises.

Also, the aligned double-walled carbon nanotube bulk structure of the present invention can be patterned in a prescribed shape. As the patterning shape, various shapes such as a cylindrical shape, a square columnar shape and complicated shapes can be employed in addition to a thin film shape.

As the patterning method of the catalyst, any method can be appropriately employed so far as it is able to pattern the catalyst metal directly or indirectly. The patterning method may be a wet process or a dry process. For example, in addition to patterning using a mask, patterning using nanoimpirnting, patterning using soft lithography, patterning using printing, patterning using plating, patterning using screen printing and patterning using lithography, a method in which other material on which the catalyst is selectively adsorbed is patterned on the substrate using any one of the foregoing methods, and the catalyst is selectively adsorbed on other material to prepare a pattern may be employed. The method is favorably patterning using lithography, metal vapor deposition photolithography using a mask, electron beam lithography, catalyst metal patterning by an electron vapor deposition method using a mask or catalyst metal patterning by a sputtering method using a mask.

The height (length) of the aligned double-walled carbon nanotube bulk structure to be produced in the process of the present invention varies depending upon the use; its lower limit is preferably 0.1 μm, more preferably 20 μm, and especially preferably 50 μm; and though its upper limit is not particularly limited, it is preferably 2.5 mm, more preferably 1 cm, and especially preferably 10 cm.

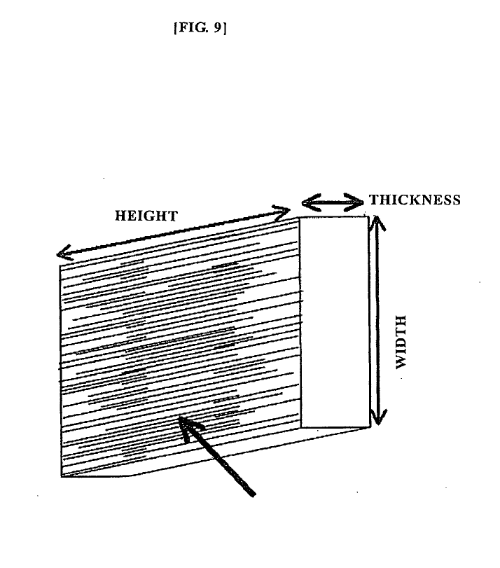

Also, according to the process of the present invention, the shape of the bulk structure can be arbitrarily controlled by the patterning of the metal catalyst and the growth of the carbon nanotube. An example of a control manner having been turned into a model is shown in FIG. 9.

This example is concerned with an example of a thin film-shaped bulk structure (the structure may be in a thin film form or a bulk form relative to the diameter dimension of the carbon nanotube), in which the thickness is thin as compared with the height and width; the width can be controlled at an arbitrary length by patterning of the catalyst; the thickness can be controlled at an arbitrary thickness by patterning of the catalyst; and the height can be controlled by the growth of each vertically aligned double-walled carbon nanotube configuring the structure. In FIG. 9, the arrangement of the vertically aligned double-walled carbon nanotube is shown by an arrow.

As a matter of course, the shape of the aligned double-walled carbon nanotube bulk structure to be produced in the process of the present invention is not limited to a thin film shape, but various shapes such as a cylindrical shape, a square columnar shape and complicated shapes can be employed through the patterning of the catalyst and the control of the growth.

In the process of the present invention, a step of breaking a by-product which deactivates the catalyst, for example, amorphous carbon or a graphite layer may be combined.

The breaking step as referred to herein means a process for appropriately eliminating a substance which is a by-product in the carbon nanotube production step and deactivates the catalyst, for example, amorphous carbon or a graphite layer but not eliminating the carbon nanotube itself. Accordingly, any process for eliminating a substance which is a by-product in the carbon nanotube production step and deactivates the catalyst can be employed as the breaking step. As such a step, oxidation and burning with an oxidizing agent, chemical etching, plasma, ion milling, microwave irradiation, ultraviolet ray irradiation and quenching and breaking can be exemplified; the use of an oxidizing agent is preferable; and the use of moisture is especially preferable.

Examples of an embodiment of a combination of the growth step and the breaking step include one for simultaneously performing the growth step and the breaking step; one for alternately performing the growth step and the breaking step; and a combination of a mode for emphasizing the growth step and a mode for emphasizing the breaking step.

As the apparatus for carrying out the process of the present invention, any of the foregoing apparatus can be used.

By such a combination of the steps, in the process of the present invention, the foregoing double-walled carbon nanotube can be produced with high efficiency without deactivating the catalyst over a long time. Furthermore, not only the oxidation and burning with an oxidizing agent but various processes including chemical etching, plasma, ion milling, microwave irradiation, ultraviolet ray irradiation and quenching and breaking can be employed. Moreover, any vapor phase or liquid phase process can be employed. Accordingly, there is brought a great advantage that a degree of freedom for selecting the production process is enhanced.

The aligned double-walled carbon nanotube bulk structure which is composed of the double-walled nanotube or plural double-walled carbon nanotubes according to the present invention, has a height of 0.1 μm or more and has a shape having been patterned in a prescribed shape has various physical properties and characteristics such as super high purity, super heat conductivity, excellent electron emission characteristic, excellent electronic or electric characteristic and super mechanical strength, and therefore, it can be applied to various technical fields and uses. In particular, a largely scaled, vertically aligned bulk structure and a patterned, vertically aligned bulk structure can be applied to the following technical fields.

### (A) Heat Dissipator (Heat Dissipation Characteristic)

CPU which is the heart of a computer of an article requiring heat dissipation, for example, an electronic article is required to have higher speed and higher integration with respect to the operational ability, the degree of heat generation from the CPU itself increases more and more, and it is said that there is a possibility that the enhancement in performance of LSI reaches limits in the near future. In the case of dissipating heat at such a density of heat generation, a heat dissipator in which a randomly aligned carbon nanotube is embedded in a polymer has hitherto been known. However, there was involved a problem that it fails in heat dissipation characteristic in the vertical direction. The foregoing large-scaled, vertically aligned carbon nanotube bulk structure according to the present invention exhibits high heat dissipation characteristic and is vertically aligned at a high density and in a longitudinal manner. Therefore, when this is utilized as a heat dissipation material, the heat dissipation characteristic in the vertical direction can be outstandingly enhanced as compared with the existent products.

The heat dissipator of the present invention is not restricted to electronic parts but can be applied to various other articles requiring heat dissipation, for example, electric appliances, optical appliances and mechanical appliances.

### (B) Heat Conductor (Heat Conductivity)

The vertically aligned carbon nanotube bulk structure of the present invention has good heat conductivity. By fabricating such a vertically aligned carbon nanotube bulk structure having excellent heat conductivity into a heat conductive material that is a composite material containing this, a high heat conductive material can be obtained. For example, when applied to a heat exchanger, a dryer, a heat pipe or the like, it is possible to devise to enhance its performance. When such a heat conductive material is applied to an aerospace heat exchanger, it is possible to devise to enhance the heat exchange performance and to reduce the weight and volume. Also, when such a heat conductive material is applied to a fuel cell cogeneration or a micro gas turbine, it is possible to devise to enhance the heat exchange performance and heat resistance.

### (C) Electric Conductor (Electric Conductivity)

Electronic parts, for example, current integrated LSIs have a structure of several layers. The via wiring refers to a wiring in the vertical direction in the inside of LSI, and a copper wiring or the like is used at present. However, following the microfabrication, breaking of wire of the via to be caused due to an electromigration phenomenon is of a problem. By replacing the copper wiring as the vertical wiring by the foregoing vertically aligned double-walled carbon nanotube bulk structure or aligned double-walled carbon nanotube bulk structure having been patterned in a prescribed shape according to the present invention, a current with a density of 1,000 times that of copper can be made to flow, and no electromigration phenomenon occurs, and therefore, it is possible to devise to achieve much more microfabrication and stabilization of the via wiring.

Also, the electric conductor of the present invention or a wired material thereof can be utilized as electric conductors or wirings of various articles, electric appliances, electronic appliances, optical appliances and mechanical appliances, all of which require electric conductivity.

For example, in view of superiority in high electric conductivity and mechanical strength of the foregoing vertically aligned double-walled carbon nanotube bulk structure or aligned double-walled carbon nanotube bulk structure having been patterned in a prescribed shape according to the present invention, by using it in place of a copper horizontal wiring in the layer, it is possible to devise to achieve microfabrication and stabilization.

### (D) Optical Element (Optical Characteristic)

In optical elements, for example, polarizer, a calcite crystal has hitherto been used. However, since this is a very large-sized and expensive optical part and does not effectively function in an ultra short wavelength region that is important in the next-generation lithography, a single-body double-walled carbon nanotube is proposed as a replacement. However, there was involved a problem that it is difficult to align this single-body double-walled carbon nanotube in a high order and to prepare a macro aligned film structure having light transmittance. The foregoing vertically aligned double-walled carbon nanotube bulk structure or aligned double-walled carbon nanotube bulk structure having been patterned in a prescribed shape according to the present invention exhibits super alignment properties, the thickness of the aligned thin film can be controlled by changing the pattern of a catalyst, and the light transmittance of the thin film can be strictly controlled. Therefore, when used as a polarizer, this shows excellent polarization characteristic in a wide wavelength band from an ultra short wavelength region to an infrared region. Also, since the ultra thin carbon nanotube aligned film functions as an optical element, the size of the polarizer can be miniaturized.

The optical element of the present invention is not restricted to the polarizer but can be applied as other optical elements utilizing its optical characteristic.

### (E) Strength Reinforcing Material (Mechanical Characteristic)

Hitherto, carbon fiber reinforced materials have a strength of 50 times as compared with aluminum and have been widely used as airplane parts, sport goods and the like as a material having light weight and strength. They are keenly demanded to have lighter weight and higher strength. Since the foregoing aligned double-walled carbon nanotube bulk structure or aligned double-walled carbon nanotube bulk structure having been patterned in a prescribed shape according to the present invention has a strength of several ten times as compared with the existent carbon fiber reinforced materials, when such a bulk structure is utilized in place of the existent carbon fiber reinforced material, products having extremely high strength can be obtained. Since this reinforcing material is light in weight and high in strength and has excellent characteristics such as high resistance to thermal oxidation (up to 300° C.), flexibility, electric conductivity, electric wave shielding properties, excellent chemical resistance and corrosion resistance, good fatigue and creep characteristics and excellent wear resistance and vibration damping properties, it can be utilized in the fields requiring light weight and strength including airplanes, sport goods and automobiles.

The reinforcing material of the present invention can also be fabricated into a high-strength composite material by blending with a base such as metals, ceramics or resins.

### (F) Super Capacitor and Secondary Battery (Electric Characteristic)

Since a super capacitor stores energy by migration of a charge, it has characteristic features that a large amount of current can be made to flow, that it endures charge and discharge exceeding 100,000 cycles and that the charging time is short. An importance performance as a super capacitor is that the static capacitance is large and that the internal resistance is low. The static capacitance is determined by the size of pore (hole), and it is known that it becomes a maximum at about 3 to 5 nanometers referred to as “meso-pore”, which agrees with the size of the double-walled carbon nanotube synthesized by the water-assisted method. Also, in the case where the foregoing aligned double-walled carbon nanotube bulk structure or aligned double-walled carbon nanotube bulk structure having been patterned in a prescribed shape according to the present invention is used, since all of the constituent elements can be optimized in parallel, and it is possible to devise to maximize the surface area of an electrode or the like, it becomes possible to minimize the internal resistance. Thus, a high-performance super capacitor can be obtained.

The aligned double-walled carbon nanotube bulk structure according to the present invention can be applied to not only the super capacitor but constituent materials of a usual super capacitor and electrode materials of secondary batteries such as a lithium cell and electrode (negative electrode) materials of a fuel cell, an air cell, etc.

### (G) Electron Emission Body

It is known that the carbon nanotube exhibits electron emission characteristic. Then, the aligned double-walled carbon nanotube according to the present invention can be expected to be applied to an electron emission element.

### EXAMPLES

The present invention will be described in more detail hereinafter by way of examples. As a matter of course, the present invention is not limited to these examples.

### Example 1

A carbon nanotube was grown by the CVD method under the following condition.

Carbon compound: Ethylene, feed rate at 200 sccm

Atmospheric (gas) (Pa): Helium and hydrogen mixed gas, feed rate at 2,000 sccm

Pressure: Atmospheric pressure

Addition amount of water vapor (ppm): 300 ppm

Reaction temperature (° C.): 750° C.

Reaction time (min): 30 minutes

Metal catalyst (existence amount): Iron thin film, 1.69 nm in thickness

Substrate: Silicon wafer

The catalyst was disposed on the substrate using a sputtering vapor deposition apparatus and vapor deposited.

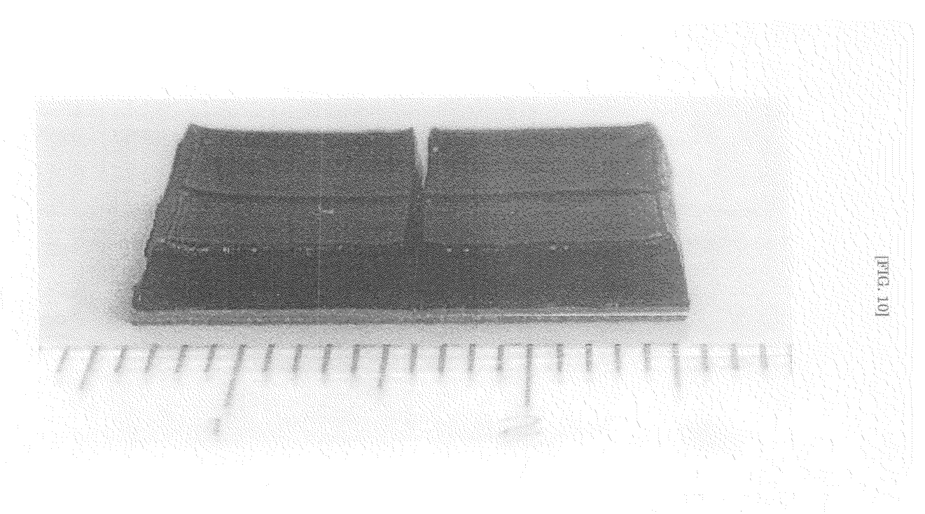

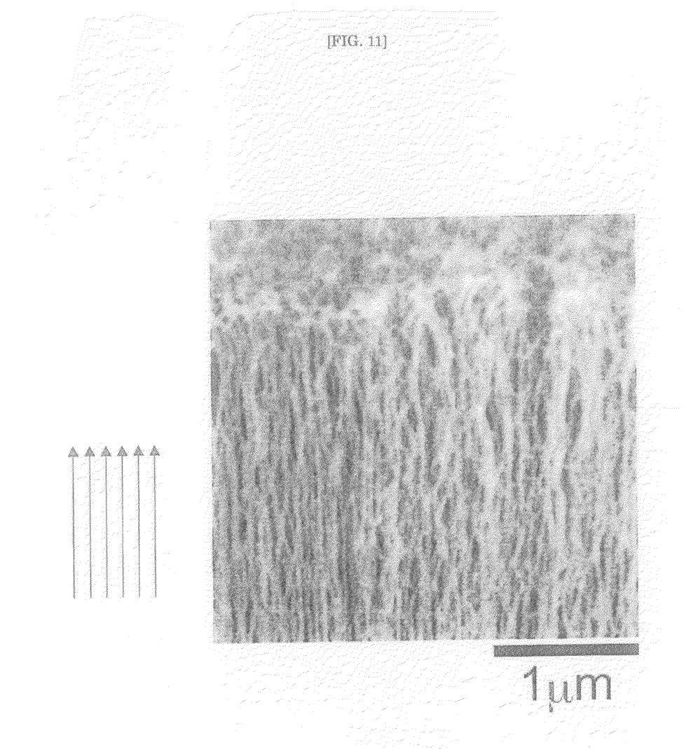

FIG. 10 exemplifies an external appearance of a vertically aligned double-walled carbon nanotube bulk structure obtained through the growth under the foregoing condition. In the drawing, the near side shows a ruler. The vertically double-walled carbon nanotube film having a height of 2.2 mm grows on the silicon wafer in the bottom. An SEM image of a vertex of this film is shown in FIG. 11. It is noted that the double-walled carbon nanotube is vertically aligned at a super-high density in the arrow directions.

In the case where the same operation as described above was performed, except for not adding water vapor, the catalyst lost the activity within several seconds, and the growth stopped after two minutes. On the other hand, in the method of Example 1 in which water vapor was added, the growth continued over a long time, and actually, continuation of the growth was observed for 30 minutes or more. Also, it was noted that the growth rate of the vertically aligned double-walled carbon nanotube of the method of Example 1 was extremely faster as about 100 times of the conventional method. Also, in the vertically aligned double-walled carbon nanotube of the method of Example 1, inclusion of the catalyst or amorphous carbon was not observed, and its purity was 99.95 mass % in a non-purified state. Furthermore, the double-walled carbon nanotube had an average outer diameter of 3.75 nm. On the other hand, for the vertically aligned carbon nanotube obtained by the conventional method, an amount that could be measured for the purity could not be obtained.

### Example 2

A carbon nanotube was grown by the CVD method under the following condition.

Carbon compound: Ethylene, feed rate at 100 sccm

Atmospheric (gas) (Pa): Helium and hydrogen mixed gas, feed rate at 1,000 sccm

Pressure: Atmospheric pressure

Addition amount of water vapor (ppm): 300 ppm

Reaction temperature (° C.): 750° C.

Reaction time (min): 10 minutes

Metal catalyst (existence amount): Iron thin film, 1.69 nm in thickness

Substrate: Silicon wafer

The catalyst was disposed on the substrate by sputtering vapor deposition.

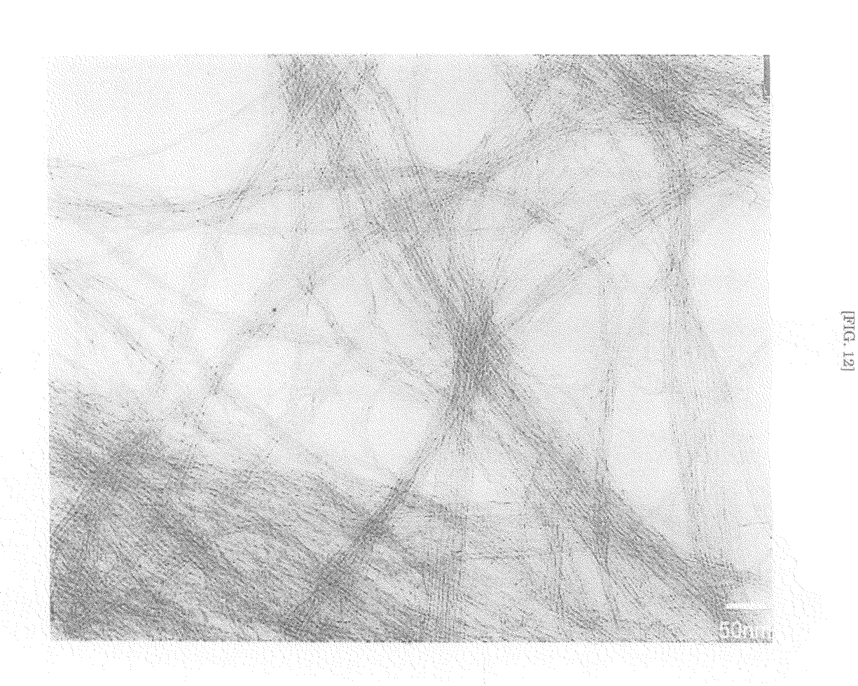

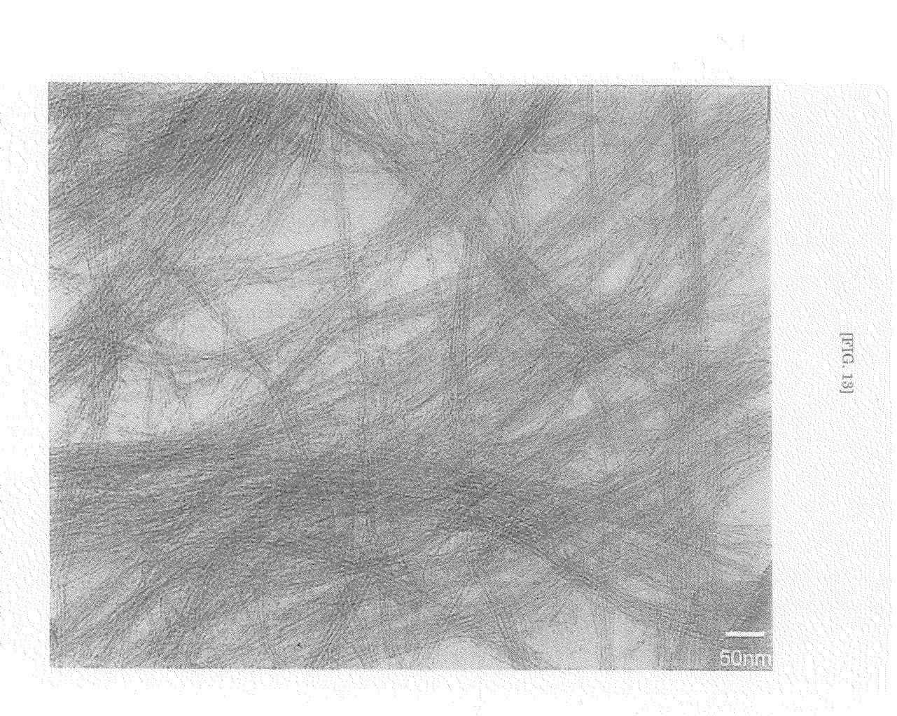

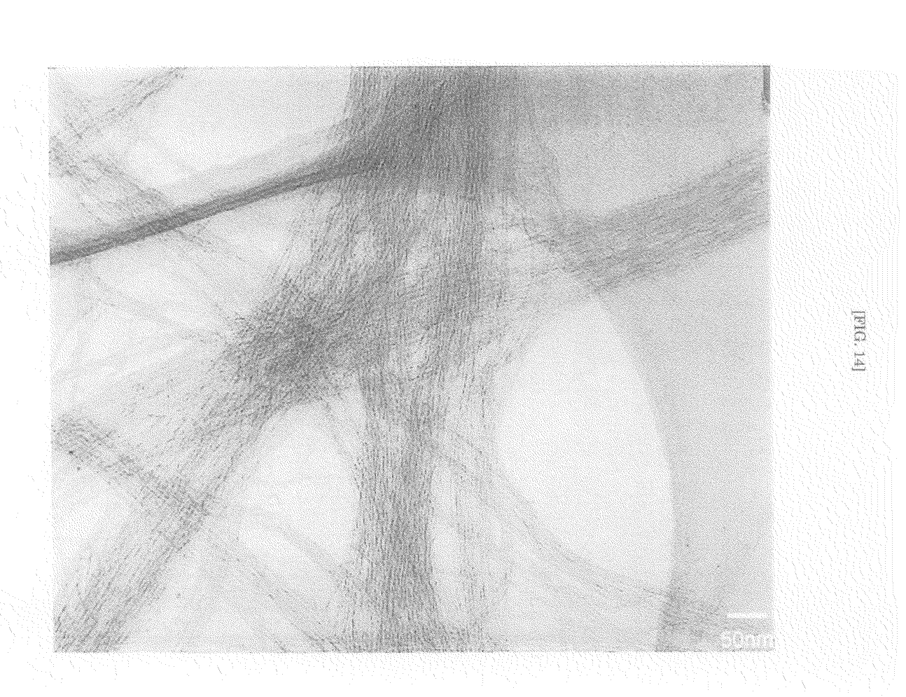

FIGS. 12 to 14 are each a photographic image obtained by peeling off the vertically aligned double-walled carbon nanotube prepared in Example 2 from the substrate using a pair of tweezers, dispersing it in a solution, placing it on a grid of an electron microscope (TEM) and observing it by an electron microscope (TEM). It is noted that neither the catalyst nor amorphous carbon is incorporated in the obtained carbon nanotube. The double-walled carbon nanotube of Example 2 was 99.95 mass % in a non-purified state.

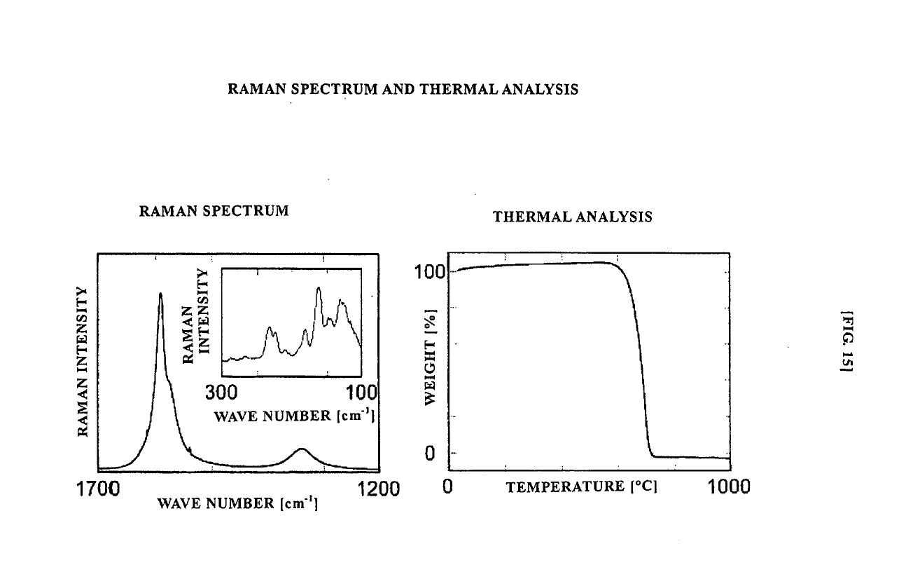

The Raman spectrum and the result of thermal weight analysis of the vertically aligned double-walled carbon nanotube prepared in Example 2 are shown in FIG. 15. According to the Raman spectrum, the G band having a sharp peak is observed at 1,592 K, and it is noted that a graphite crystal structure is present. Also, in view of the matter that the D band (1,340 K) is small, it is noted that the vertically aligned double-walled carbon nanotube is small in a defect and high in quality. Then, it is noted from the peak on the low wavelength side that the graphite layer is a double-walled carbon nanotube.

Also, it is noted from the result of the thermal analysis that a reduction in weight is low at low temperatures and that no amorphous carbon is present. Also, it is noted that the carbon nanotube has a high burning temperature and high quality (high purity).

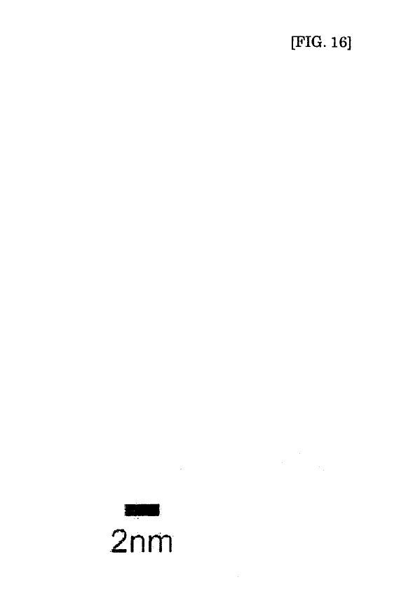

FIG. 16 is an electron microscopic (TEM) photographic image obtained by enlarging the peeled-off vertically aligned double-walled carbon nanotube. It is noted that the obtained material is a vertically aligned double-walled carbon nanotube. Such a vertically aligned double-walled carbon nanotube had an average outer diameter of 3.75 nm.

### Example 3

A carbon nanotube was grown by the CVD method under the following condition.

Carbon compound: Ethylene, feed rate at 100 sccm

Atmospheric (gas): Helium and hydrogen mixed gas, feed rate at 1,000 sccm

Pressure: Atmospheric pressure

Addition amount of water vapor (ppm): 300 ppm

Reaction temperature (° C.): 750° C.

Reaction time (min): 10 minutes

Metal catalyst (existence amount): Iron thin film, 0.94, 1.32, 1.62, 1.65, 1.69 and 1.77 nm in thickness

Substrate: Silicon wafer

The catalyst having each thickness was disposed on the substrate by sputtering vapor deposition.

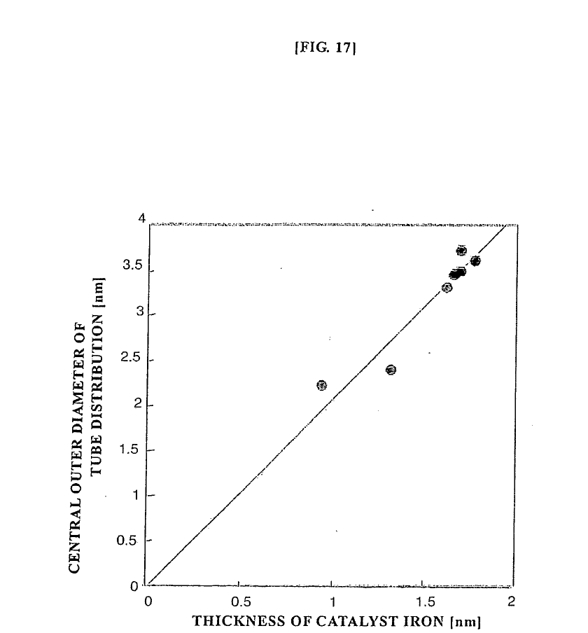

FIG. 17 shows the relationship of a thickness of each iron film and a center of outer diameter distribution of the carbon nanotube; and the proportions (%) of single-walled, double-walled and triple-walled or multi-walled nanotubes are shown in the following Table 1.

TABLE 1

| Thickness of | Double-walled | Single-walled | Multi-walled |
|---|---|---|---|
| iron film [nm] | [%] | [%] | [%] |
| 0.94 | 8.59 | 87.1 | 4.29 |
| 1.32 | 11.6 | 81.5 | 6.85 |
| 1.62 | 57.1 | 15.2 | 27.7 |
| 1.65 | 73.7 | 14.0 | 12.3 |
| 1.69 | 85.0 | 4.42 | 10.6 |
| 1.77 | 66.0 | 6.0 | 28.0 |

It is noted from Table 1 that the proportion of the double-walled carbon nanotube account for 50% or more at a thickness of iron film in the range of from 1.5 nm to 2.0 nm and 85% at 1.69 nm.

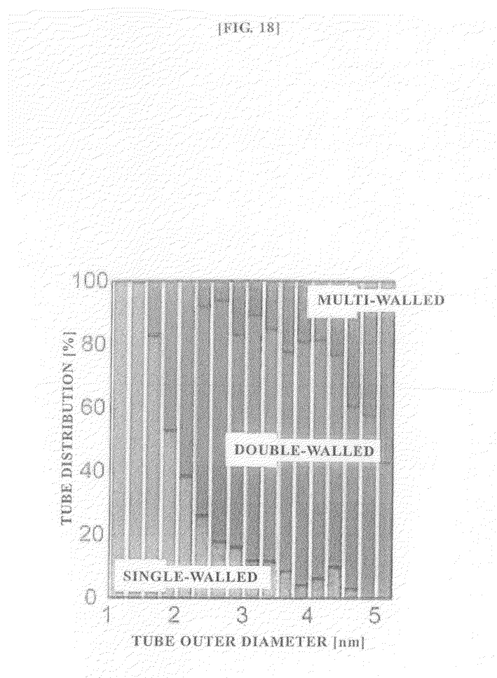

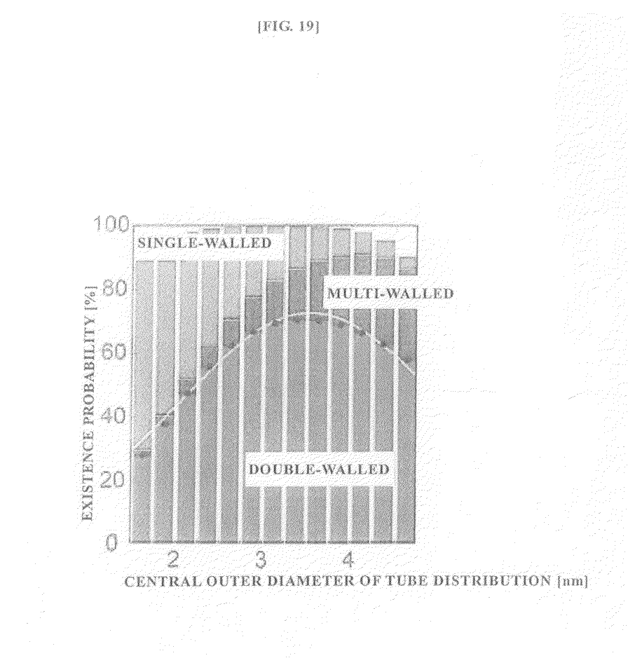

Then, from FIG. 17 and Table 1, there is a correlation between the tube outer diameter and the tube distribution as shown in FIG. 18, and the double-walled nanotube concentration by diameter can be expected from this correlation and gauss distribution owned by the nanotube. This is shown in FIG. 19. This FIG. 19 expresses a concentration of the double-walled nanotube when it has a certain average diameter, which is obtained by evaluating a half-value width of the gauss distribution of diameter owned by the nanotube as 1.4 and calculating from the diameter correlation of the double-walled nanotube concentration.

It is noted from this that it is possible to achieve design by controlling the proportions of the double-walled, single-walled and triple-walled or multi-walled nanotubes by the fabrication amount (thickness) of the catalyst.

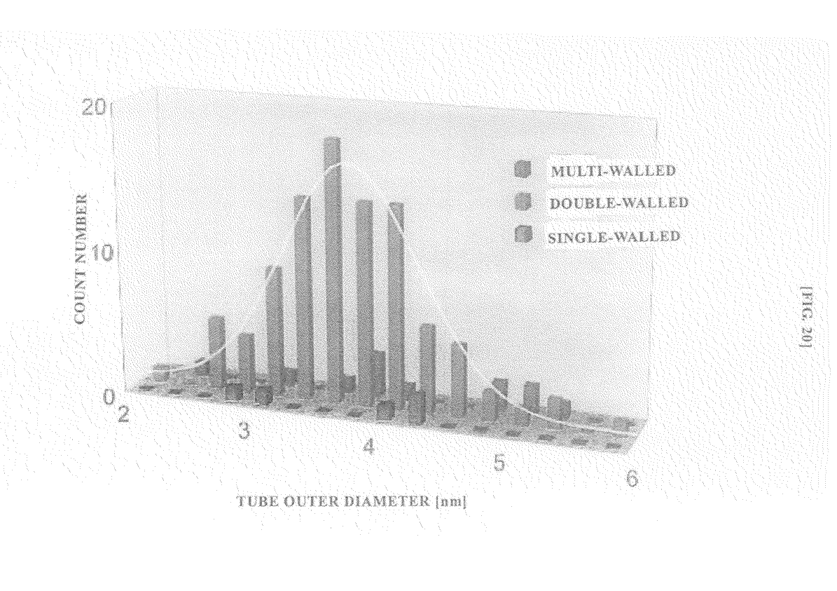

FIG. 20 shows the relationship between a tube outer diameter and a count number regarding an example of high-concentration double-walled nanotube.

### Reference Example

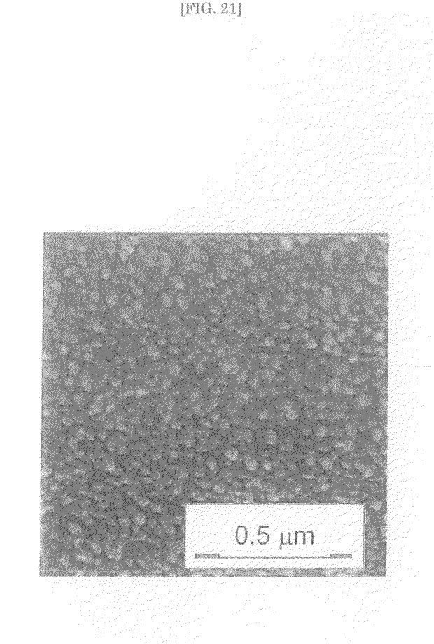

It was confirmed from the following fact that the thin film-shaped metal catalyst is finely divided by heating. That is, a thin film-shaped catalyst corresponding to Example 1 was finely divided by a thermal history equivalent to the growth of the double-walled carbon nanotube and cooled without performing the growth, followed by observation by an atomic force microscope. The result of the observation was exemplified in FIG. 21.

It is noted from this FIG. 21 that the metal thin film catalyst became a fine particle having a diameter of several nanometers (measured in terms of a height) (since the atomic force microscope has a resolving power of only several ten nanometers in a lateral direction, the catalyst is seen largely).

### Example 4

An aligned double-walled carbon nanotube bulk structure was grown by the CVD method under the following condition.

Carbon compound: Ethylene, feed rate at 100 sccm

Atmospheric (gas): Helium and hydrogen mixed gas, feed rate at 1,000 sccm

Pressure: Atmospheric pressure

Addition amount of water vapor (ppm): 400 ppm

Reaction temperature (° C.): 750° C.

Reaction time (min): 10 minutes

Metal catalyst (existence amount): Iron thin film, 1.69 nm in thickness

Substrate: Silicon wafer

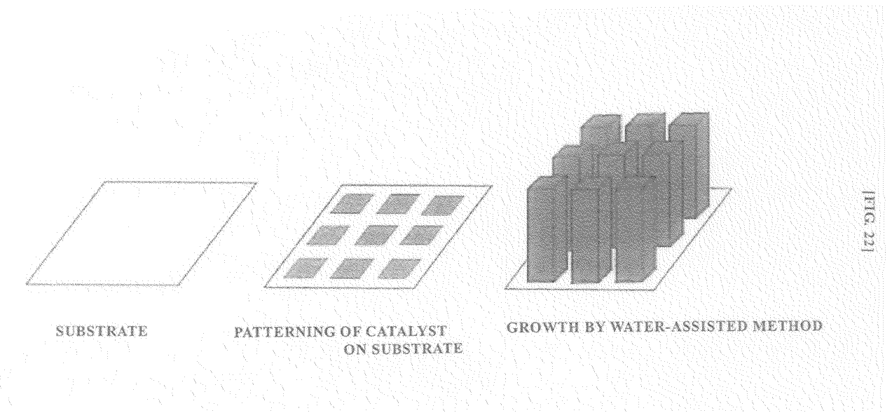

The disposition of the catalyst on the substrate and the growth of the tube were carried out in conformity with a process shown in FIG. 22 in the following manner.

A resist for electron beam exposure, ZEP-520A was thinly stuck on a silicon wafer at 4,700 rpm for 60 seconds using a spin coater and baked at 200° C. for 3 minutes. Next, a pattern having a thickness of from 3 to 1,005 μm, a length of from 375 μm to 5 mm and a gap of from 10 μm to 1 mm was prepared on the foregoing resist-stuck substrate using an electron beam exposure apparatus. Next, an iron metal having a thickness of 1.69 nm was vapor deposited using a sputtering vapor deposition apparatus; and finally, the resist was peeled off from the substrate using a peeling-off liquid ZD-MAC, thereby preparing a silicon wafer substrate having been arbitrarily patterned with the catalyst metal.

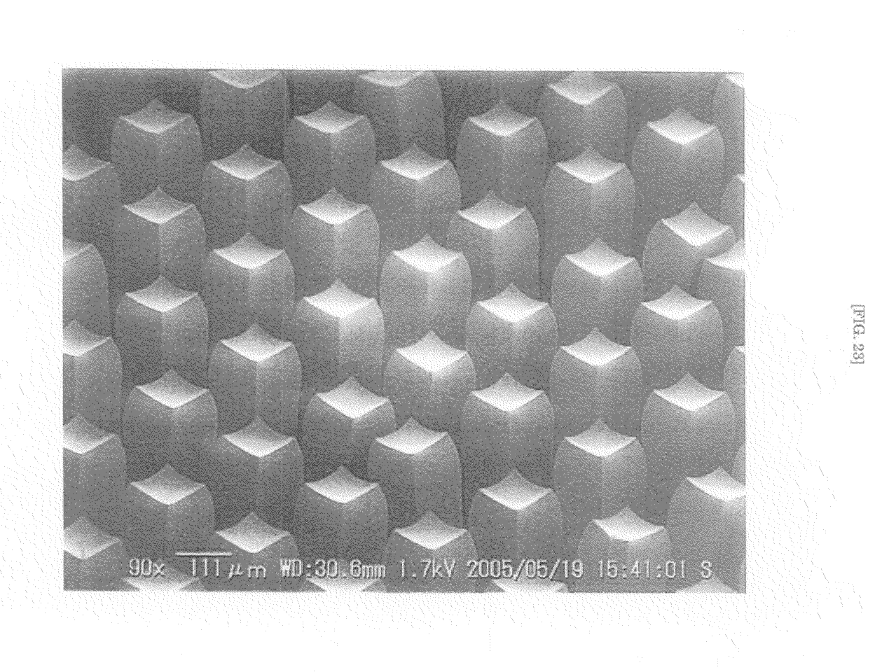

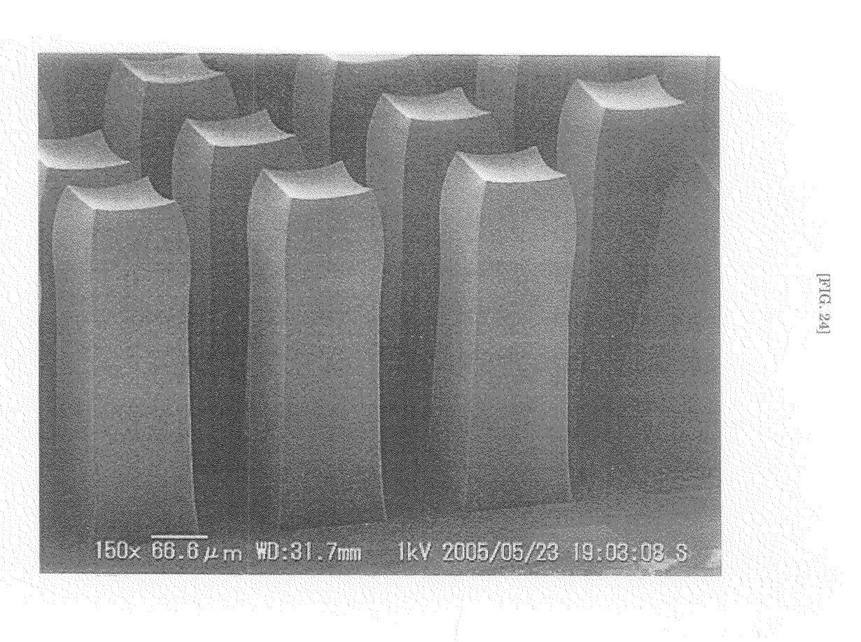

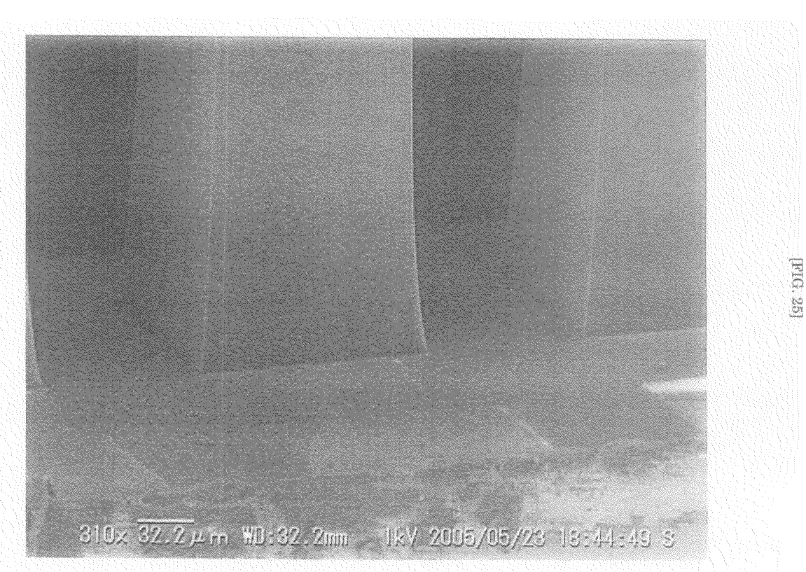

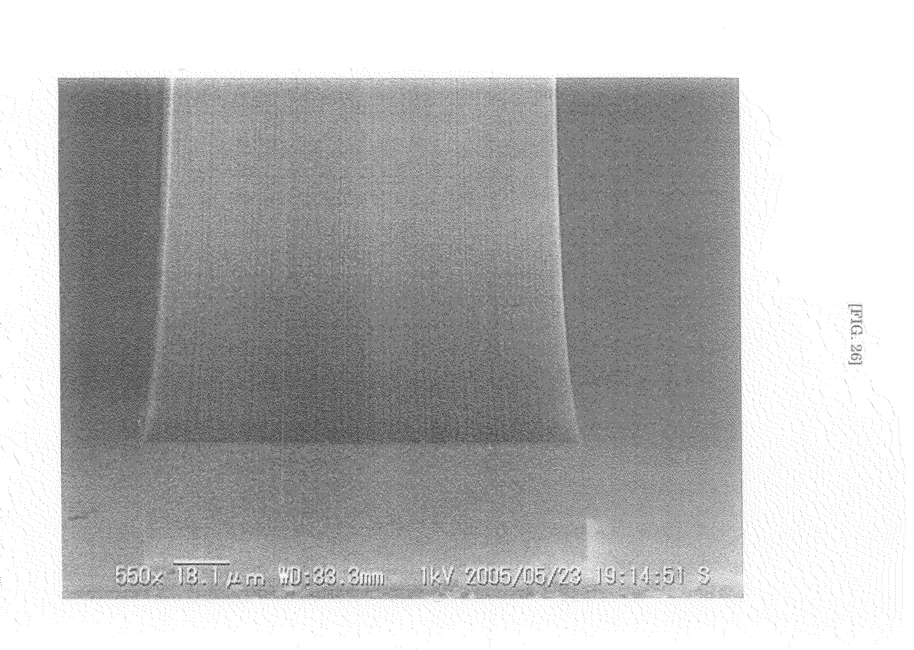

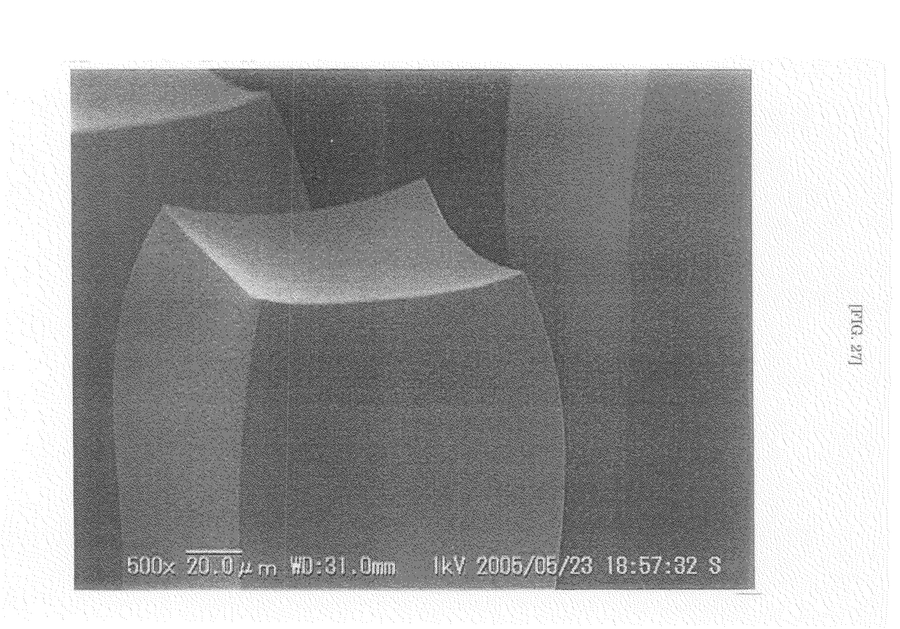

FIGS. 23 to 27 each shows an electron microscopic (SEM) photographic image of the formed aligned double-walled carbon nanotube bulk structure. FIGS. 25 and 26 each shows an SEM image of the root; and FIG. 27 shows an SEM image of the top.

### Example 5

With respect to the high-purity double-walled carbon nanotube fabricated in Example 2, the measurement of nitrogen adsorption isotherm and the evaluation of specific surface area were carried out under the conditions as shown in the following Table 2.

TABLE 2

| | |
|---|---|
| Adsorption gas: | Nitrogen |
| Adsorption and desorption | 77° K |
| temperature: | |
| Adsorption apparatus: | BELSORP-MINI 2 (manufactured by |
| | Bel Japan, Inc.) |
| Pre-treatment temperature: | 300° C. |
| Pre-treatment time: | 12 hours |
| Pre-treatment atmosphere: | Vacuum |
| Evaluation of specific surface area: | Analyzed from nitrogen adsorption |
| | isotherm by the BET method |

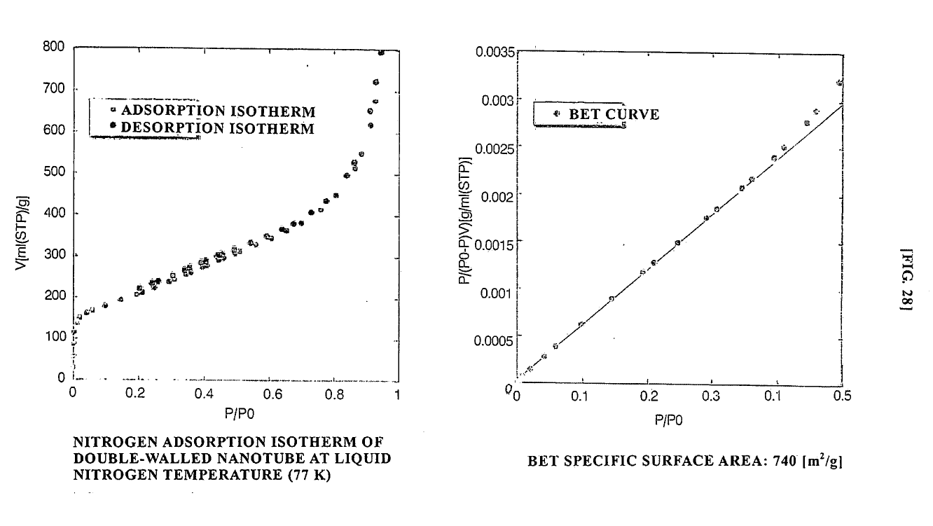

The obtained results are shown in FIG. 28. The BET specific surface area is decided to be 740 m²/g.

### Example 6

### Electric Conductor

The aligned double-walled carbon nanotube bulk structure obtained in Example 2 was formed into a shape of 1 cm×1 cm×1 mm in height; copper plates were brought into contact with the upper side and the lower side; and electric resistance was evaluated by the 2-terminal method using a Custom's digital tester (CDM-2000D). As a result, the measured resistance value was 4Ω. This resistance values includes two kinds of the conduction resistance through the aligned double-walled carbon nanotube bulk structure and the contact resistance of the aligned double-walled carbon nanotube bulk structure and the copper electrode and shows that the aligned double-walled carbon nanotube bulk structure and the metal electrode can be brought into intimate contact with each other at a low contact resistance. From this, it can be expected that the aligned double-walled carbon nanotube bulk structure is useful as an electric conductor.

1. A double-walled carbon nanotube, characterized by having an average outer diameter of 1 nm or more and 6 nm or less and a purity of 98 mass % or more.

2. The double-walled carbon nanotube according to claim 1, wherein its proportion under the coexistence of at least one of a single-walled carbon nanotube and a multi-walled carbon nanotube having three or more walls is 50% or more.

3. The double-walled carbon nanotube according to claim 1, wherein it is aligned.

4. The double-walled carbon nanotube according to claim 3, wherein it is vertically aligned on a substrate.

5. A process for producing a double-walled carbon nanotube by a method of chemically vapor depositing (CVD) a carbon nanotube in the presence of a metal catalyst, characterized by selectively growing the carbon nanotube by controlling the particle size of a fine particle metal catalyst.

6. The process for producing a double-walled carbon nanotube according to claim 5, wherein in forming a fine particle metal catalyst by heating a thin film-shaped metal catalyst, the particle size of the fine particle of the metal catalyst is controlled corresponding to the thickness of the thin film.

7. The process for producing a double-walled carbon nanotube according to claim 5, wherein the carbon nanotube is selectively grown by controlling the particle size of a catalyst metal such that its proportion under the coexistence of at least one of a single-walled carbon nanotube and a multi-walled carbon nanotube having three or more walls is 50% or more.

8. The process for producing a double-walled carbon nanotube according to claim 5, wherein iron is used as the catalyst metal, and its thickness is controlled at 1.5 nm or more and 2.0 nm or less.

9. The process for producing a double-walled carbon nanotube according to claim 5, wherein an oxidizing agent is made present in a reaction atmosphere.

10. The process for producing a double-walled carbon nanotube according to claim 9, wherein the oxidizing agent is water.

11. The process for producing a double-walled carbon nanotube according to claim 10, wherein moisture of 10 ppm or more and 10,000 ppm or less is made present.

12. The process for producing a double-walled carbon nanotube according to claim 10, wherein water vapor is made present at a temperature of 600° C. or higher and 1,000° C. or lower.

13. The process for producing a double-walled carbon nanotube according to claim 5, wherein the catalyst is disposed on a substrate, thereby growing the vertically aligned double-walled carbon nanotube on the surface of the substrate.

14. The process for producing a double-walled carbon nanotube according to claim 5, wherein a double-walled carbon nanotube having a length of 10 μm or more is obtained.

15. The process for producing a double-walled carbon nanotube according to claim 5, wherein a double-walled carbon nanotube having a length of 10 μm or more and 10 cm or less is obtained.

16. The process for producing a double-walled carbon nanotube according to claim 5, wherein after growing, the double-walled carbon nanotube is separated from the catalyst or substrate without exposing to a solution and a solvent.

17. The process for producing a double-walled carbon nanotube according to claim 5, wherein a double-walled carbon nanotube having a purity of 98 mass % or more is obtained.

18. The process for producing a double-walled carbon nanotube according to claim 5, wherein a double-walled carbon nanotube having an average outer diameter of 1 nm or more and 6 nm or less is obtained.

19. An aligned double-walled carbon nanotube bulk structure, which is characterized by comprising plural aligned double-walled carbon nanotubes having an outer diameter of 1 nm or more and 6 nm or less and a purity of 98 mass % or more.

20. The aligned double-walled carbon nanotube bulk structure according to claim 19, wherein it has a height of 0.1 μm or more and 10 cm or less.

21. The aligned double-walled carbon nanotube bulk structure according to claim 19, wherein a proportion of the double-walled carbon nanotube under the coexistence of at least one of a single-walled carbon nanotube and a multi-walled carbon nanotube having three or more walls is 50% or more.

22. The aligned double-walled carbon nanotube bulk structure according to claim 19, wherein it exhibits anisotropy in at least one of optical characteristic, electric characteristic, mechanical characteristic, magnetic characteristic and thermal characteristic in the alignment direction and the vertical direction thereto.

23. The aligned double-walled carbon nanotube bulk structure according to claim 22, wherein with respect to a degree of anisotropy in the alignment direction and the vertical direction thereto, a larger value is 1:3 or more relative to a smaller value.

24. The aligned double-walled carbon nanotube bulk structure according to claim 19, wherein the shape of the bulk structure is patterned into a prescribed shape.

25. The aligned double-walled carbon nanotube bulk structure according to claim 19, wherein it is vertically aligned on a substrate.

26. The aligned double-walled carbon nanotube bulk structure according to claim 19, wherein the bulk structure is a thin film.

27. A process for producing an aligned double-walled carbon nanotube bulk structure by patterning a metal catalyst on a substrate and chemically vapor depositing (CVD) plural carbon nanotubes in the presence of the metal catalyst such that they are aligned in a prescribed direction relative to the surface of the substrate to form a bulk structure, characterized by selectively growing a double-walled carbon nanotube by controlling the particle size of the metal catalyst as a fine particle.

28. The process for producing an aligned double-walled carbon nanotube bulk structure according to claim 27, wherein in forming a fine particle metal catalyst by heating a thin film of the metal catalyst, the particle size of the metal catalyst fine particle is controlled corresponding to the thickness of the thin film.

29. The process for producing an aligned double-walled carbon nanotube bulk structure according to claim 27, wherein the carbon nanotube is selectively grown by controlling the particle size of the metal catalyst such that its proportion under the coexistence of at least one of a single-walled carbon nanotube and a multi-walled carbon nanotube having three or more walls is 50% or more.

30. The process for producing an aligned double-walled carbon nanotube bulk structure according to claim 28, wherein iron is used as the metal catalyst, and its thickness is controlled at 1.5 nm or more and 2.0 nm or less.

31. The process for producing an aligned double-walled carbon nanotube bulk structure according to claim 27, wherein an oxidizing agent is made present in a reaction atmosphere.

32. The process for producing an aligned double-walled carbon nanotube bulk structure according to claim 31, wherein the oxidizing agent is water.

33. The process for producing an aligned double-walled carbon nanotube bulk structure according to claim 32, wherein moisture of 10 ppm or more and 10,000 ppm or less is made present.

34. The process for producing an aligned double-walled carbon nanotube bulk structure according to claim 32, wherein moisture is made present at a temperature of 600° C. or higher and not higher than 1,000° C.

35. The process for producing an aligned double-walled carbon nanotube bulk structure according to claim 27, wherein a bulk structure having a height of 0.1 μm or more and 10 cm or less is obtained.

36. The process for producing an aligned double-walled carbon nanotube bulk structure according to claim 27, wherein the shape of the bulk structure is controlled by patterning of the metal catalyst and growth of the carbon nanotube.

37. The process for producing an aligned double-walled carbon nanotube bulk structure according to claim 27, wherein after growing, the bulk structure is separated from the catalyst or substrate without exposing to a solution and a solvent.

38. The process for producing an aligned double-walled carbon nanotube bulk structure according to claim 27, wherein a bulk structure having an average outer diameter of 1 nm or more and 6 nm or less and a purity of 98 mass % or more is obtained.

39. The process for producing an aligned double-walled carbon nanotube bulk structure according to claim 27, wherein a bulk structure having anisotropy in at least one of optical characteristic, electric characteristic, mechanical characteristic, magnetic characteristic and thermal characteristic in the alignment direction and the vertical direction thereto is obtained.

40. The process for producing an aligned double-walled carbon nanotube bulk structure according to claim 39, wherein a bulk structure in which with respect to a degree of anisotropy in the alignment direction and the vertical direction thereto, a larger value is 1:3 or more relative to a smaller value is obtained.

41. The process for producing an aligned double-walled carbon nanotube bulk structure according to claim 27, wherein the alignment of the prescribed direction is vertical alignment.
